(19) United States
(12) Patent Application Publication
(10) Pub. No.: US 2017/0117402 A1
(43) Pub. Date: Apr. 27, 2017

(54) SEMICONDUCTOR DEVICE AND METHOD OF PRODUCING THE SAME

(71) Applicant: Sumitomo Electric Industries, Ltd., Osaka-shi (JP)

(72) Inventor: Masatoshi Koyama, Yokohama-shi (JP)

(21) Appl. No.: 15/299,056

(22) Filed: Oct. 20, 2016

(30) Foreign Application Priority Data
Oct. 21, 2015 (JP) 2015-207341

(51) Int. Cl. H01L 29/778; H01L 21/324; H01L 29/66

(52) U.S. Cl. CPC H01L 29/7787; H01L 29/66462; H01L 21/3245

(57) ABSTRACT

A process of forming a semiconductor device type of high electron-mobility transistor (HEMT) made of nitride semiconductor materials, and a HEMT formed thereby are disclosed. The process includes steps of implanting impurities into regions corresponding to n+ regions, activating the impurities by annealing, removing a disarranged region between the n+ regions, and forming the gate electrode onto the region where the disarranged region is removed in advance to the formation. The annealing, even when an insulating film covers the surface, causes the disarranged region primarily due to the sublimation of nitrogen (N). When the gate electrode is formed on the disarranged region, leak currents between the electrodes become substantial. Contrary, the HEMT of the invention provides the gate electrode onto a surface where the disarranged region is removed.

### BACKGROUND OF INVENTION

1. Field of the Invention

The present invention relates to a process of forming a nitride semiconductor device type of high electron mobility transistor (HEMT).

2. Background Arts

A semiconductor electron device using nitride semiconductor materials have been practically popular in a field because of superior breakdown voltages inherently attributed to the nitride semiconductor materials. A semiconductor device type of HEMT is widely used in the field. Recht; F et al., has reported in IEEE Electron Device Letters, vol. 27 (2006) pages 205 to 207, a HEMT having n+ regions beneath a source electrode and a drain electrode in order to improve contact resistance of those electrodes.

The n+ regions may be formed by implanting ions accompanied with subsequent annealing at a temperature higher than 1000° C. in order to activate implanted ions. However, such annealing sometimes degrades the quality of the mother semiconductor materials to be processed; in particular, a surface of the semiconductor material is possibly damaged during the annealing. Specifically, nitrogen (N) that shows relatively higher vapor pressure may be easily sublimated from the surface of the semiconductor material, which degrades the stoichiometry of the material in a region adjacent to the surface. Such a surface region degraded in the stoichiometry thereof may increase leak currents between the electrodes and degrade the long-term reliability of the device.

One technique that may solve the subject above has been known. That is, a protection film made of inorganic material covers the surface of the material during the annealing. The protection film is typically made of silicon nitride (SiN) formed by the plasma enhance chemical vapor deposition (p-CVD) technique. However, even such an inorganic film covers the surface; the inorganic film may not thoroughly protect the nitrogen (N) from sublimating from the surface. A silicon oxide (SiOx) is known as a material substitutable for SiN; but SiON easily causes oxidization of the surface.

### SUMMARY OF INVENTION

The first aspect of the present application relates to a process of making a semiconductor type of high electron-mobility transistor (HEMT) made of nitride semiconductor materials. The process may include steps of: (a) growing a semiconductor stack that includes a buffer layer, a channel layer, a barrier layer, and a cap layer on a substrate; (b) implanting impurities into first regions of the semiconductor stack that correspond to a source region and a drain region, respectively; (c) forming an insulating film onto the semiconductor stack; (d) annealing the substrate and the semiconductor stack with the insulating film, where the semiconductor stack causes a disarranged region in a surface thereof and a region adjacent to the surface during the annealing; (e) removing the insulating film; (f) removing at least a portion of the disarranged region extending fully between the first regions so as to form a second region between the first regions; and (g) forming a gate electrode onto the semiconductor stack in the second region.

The second aspect of the present application relates to a semiconductor device type of high electron-mobility transistor (HEMT) made of nitride semiconductor materials. The HEMT includes a semiconductor stack on a substrate, n+ regions within the semiconductor stack, an insulating film on the semiconductor stack, a gate electrode, and source and drain electrodes. The semiconductor stack includes a buffer layer, a channel layer, a barrier layer, and a cap layer from the side of the substrate in this order. The n+ regions within the semiconductor stack are laterally apart from each other with a space therebetween and include implanted impurities. The insulating film covers a surface of the semiconductor stack in the space and has an opening. The gate electrode is directly in contact to the surface of the semiconductor stack through the opening. The source electrode and the drain electrode are provided on the surfaces of the n+ regions, respectively. A feature of the HEMT of the present application is that the surface of the semiconductor stack in the space in a level thereof is lower than the surfaces of the n+ regions.

### BRIEF DESCRIPTION OF DRAWINGS

The foregoing and other purposes, aspects and advantages will be better understood from the following detailed description of a preferred embodiment of the invention with reference to the drawings, in which:

FIG. 1 shows a cross section of a semiconductor device type of high electron-mobility transistor (HEMT) according to embodiment of the present invention;

FIGS. 2A to 2C show processes of forming the HEMT indicated in FIG. 1;

FIGS. 3A to 3C show processes of forming the HEMT subsequent to the process shown in FIG. 2C;

FIGS. 4A to 4C show processes of forming the HEMT subsequent to the process shown in FIG. 3C;

FIGS. 5A to 5C show processes of forming the HEMT subsequent to the process shown in FIG. 4C;

FIG. 6 shows a cross section of a HEMT modified from the HEMT shown in FIG. 1;

FIGS. 7A and 7B show cross sections of HEMTs each modified from the HEMT shown in FIG. 1;

FIG. 8 shows a cross section of a HEMT still modified from the HEMT shown in FIG. 1; and

FIG. 9 shows a cross section of a HEMT still modified from the HEMT shown in FIG. 1.

### DESCRIPTION OF EMBODIMENT

Next, embodiment of a semiconductor device according to the present invention will be described as referring to accompanying drawings. In the description of the drawings, numerals or symbols same with or similar to each other will refer to elements same with or similar to each other without duplicating explanations.

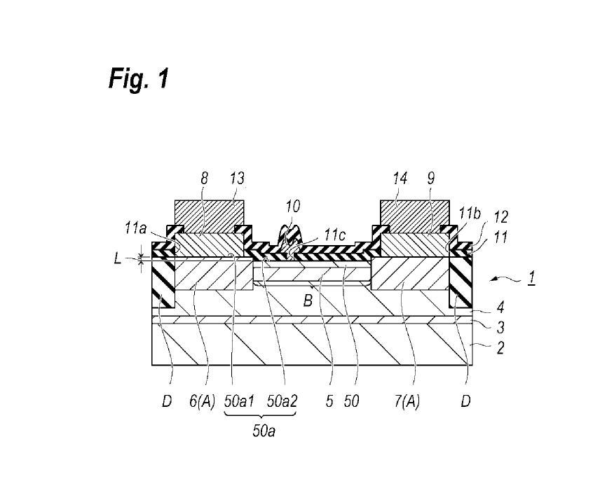

FIG. 1 shows a cross section of a semiconductor device according to the present inventions. The semiconductor device, which has a type of transistor of, what is called, a high electron-mobility transistor (HEMT), includes a substrate 2, a buffer layer 3, a channel layer 4, a barrier layer 5, a cap layer 50, n+ regions, 6 and 7, electrodes of a source 8, a drain 9, and a gate 10, and an insulating film 11. The HEMT 1 also provides a passivation film 12 that covers whole of the insulating film 11 and the electrodes 8 to 10. The source electrode 8 and the gate electrode 9 are connected to respective interconnections, 13 and 14, through openings formed in the passivation film 12. The HEMT 1 in the channel layer 4, the barrier layer 5, and the cap layer 50 thereof is electrically isolated from other HEMTs formed in the substrate 2 by isolation regions D provided outside of the n+ regions, 6 and 7. The HEMT 1 thus configured inherently forms a two dimensional electron gas (2DEG) in an interface between the channel layer 4 and the barrier layer 5, exactly, in the channel layer 4 adjacent to the interface against the barrier layer 5, and the 2DEG may operate as a channel for the carrier transportation.

The HEMET 1, as described above, includes a semiconductor stack formed by the channel layer 4, the barrier layer 5, and the cap layer 50 are made of nitride semiconductor materials, where the semiconductor stack is divided into two regions, A and B. The former region A includes the n+ regions, 6 and 7, while, the latter region B includes the cap layer 50 and the barrier layer 5 that fully extend between the first regions A.

The substrate 2, which operates as a base for a crystal growth, may be made of, for instance, silicon (Si), silicon carbide (SiC), sapphire (Al₂O₃), aluminum nitride (AlN), diamond (C), and so on. The HEMT 1 of the present embodiment provides the substrate made of SiC. The buffer layer 3, which is epitaxially grown on the substrate 2, may be made of aluminum nitride (AlN) or aluminum gallium nitride (AlGaN) with a thickness of not thinner than 5 nm but not thicker than 50 nm. The buffer layer 3 preferably has resistivity greater than that of the channel layer 4.

The channel layer 4, which is also epitaxially grown on the buffer layer 3, may be made of nitride semiconductor material, typically, gallium nitride (GaN) with a thickness of not thinner than 0.3 μm but not thicker than 3.0 μm. As described, the channel layer 4 in a side opposite to the buffer layer 3 forms the channel for the carrier transportation. The barrier layer 5, which is also epitaxially grown on the channel layer 4, may be made of nitride semiconductor material having the electron affinity greater than that of the channel layer 4. Typical materials for the barrier layer 5 are AlGaN, indium aluminum nitride (InAlN), or indium aluminum gallium nitride (InAlGaN). The barrier layer 5 of the present HEMT 1 has the barrier layer 5 made of AlGaN with a thickness of not thinner than 1 nm but not greater than 30 nm.

The cap layer 50, which is also epitaxially grown on the barrier layer 5, may be made of nitride semiconductor material containing gallium, for instance, gallium nitride (GaN), with a thickness of not thinner than 0.5 nm but not thicker than 10 nm. The cap layer 50 in a top surface 50a thereof may divided in two portions, one of which 50a1 corresponds to a surface of the first region A, while, the other 50a2 corresponds to a surface of the second region B. The former surface 50a1 sticks out from the latter surface 50a2 as forming a step with a height of not smaller than 1 nm but not greater than 3 nm. The second surface 50a2 has a composition ratio of gallium (Ga) against nitrogen (N), namely Ga/N, smaller than that of the first surface 50a1. A surface 50a of the cap layer 50 may be regarded as the stoichiometry as the composition ratio Ga/N becomes closer to unity.

The n+ regions, 6 and 7, may be formed by implanting impurities into the barrier layer 5 and the channel layer 4 by a depth of not shallower than 5 nm but not deeper than 300 nm. The impurities to be implanted into the n+ regions, 6 and 7, may be silicon (Si) or other atoms or ions behaving as n-type dopants in the cap layer 50, the barrier layer 5 and the channel layer 4. The source and drain electrodes, 8 and 9, which are provided on the cap layer 50, exactly, the source electrode 8 is provided on and in contact to the n+ region 6; while, the drain electrode 9 is provided on and in contact to the other n+ region 7. The source and drain electrodes, 8 and 9, may be a stack of titanium (Ti) and aluminum (Al), where Ti is in contact to the n+ regions, 6 and 7. The aluminum (Al) may be sandwiched by another titanium (Ti) by further staking the other titanium (Ti) on the aluminum (Al).

The gate electrode 10 is provided on the cap layer 50 and between the n+ regions, 6 and 7; that is, the gate electrode 10 is in contact to the surface 50a2 in the second region B of the cap layer 50 that extends fully between the n+ regions, 6 and 7. The gate electrode 10 may be a stack of nickel (Ni) and gold (Au), where Ni is in contact to the barrier layer 5. The insulating film 11, which covers the surface 50a of the cap layer 50, provides openings, 11a to 11c, each corresponding to the source to gate electrodes, 8 to 10. That is, the electrodes, 8 and 10, are in contact to the surface 50a of the cap layer 50 exposed within the openings, 11a to 11c, respectively. The insulating film 11 may be made of silicon nitride (SiN).

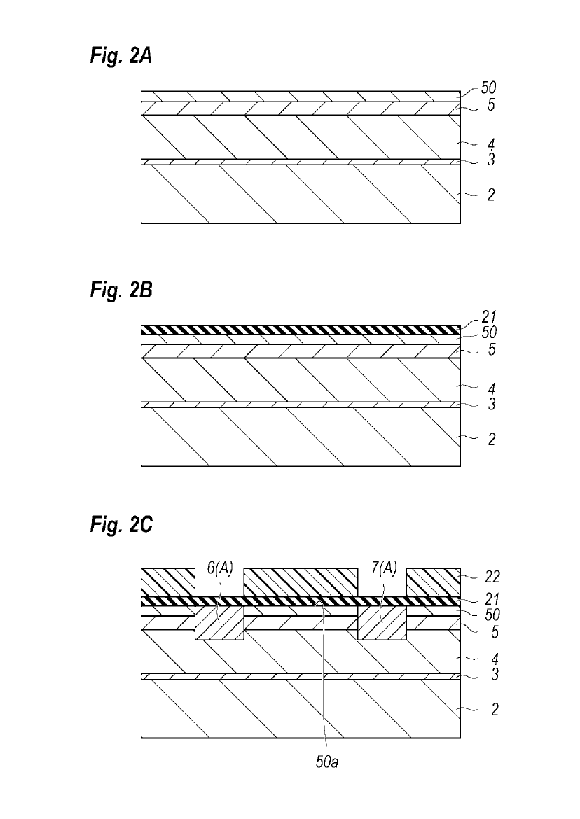

Next, a process of forming an electron device 1 type of HEMT will be described as referring to FIGS. 2A to 5C, each showing cross sections at respective steps of the process.

First, the process sequentially grows the buffer layer 3, the channel layer 4, the barrier layer 5, and the cap layer 50 on the substrate 2 by the Metal Organic Vapor Phase Epitaxy (MOVPE) technique, as shown in FIG. 2A. The buffer layer 3, the channel layer 4, the barrier layer 5, and the cap layer 50 may be made of aluminum nitride (AlN), gallium nitride (GaN), aluminum gallium nitride (AlGaN), and gallium nitride (GaN), respectively, in the present embodiment. Then, silicon nitride (SiN) is deposited on the cap layer 50 by, for instance, Plasma Enhanced Chemical Vapor Deposition (PE-CVD) technique as a through film 21 for the impurity implantation (FIG. 2B). After preparing a patterned photoresist 22 on the through film 21, the process implants silicon ions (Si⁺) within the cap layer 50, the barrier layer 5 and the channel layer 4 through the through film 21. The patterned photoresist 22 has openings in regions where the n+ regions, 6 and 7, are to be formed, as shown in FIG. 2C; that is the openings in the patterned photoresist 22 correspond to the first region A. The through film 21 may shift a profile of the implanted impurities toward the surface of the cap layer 50.

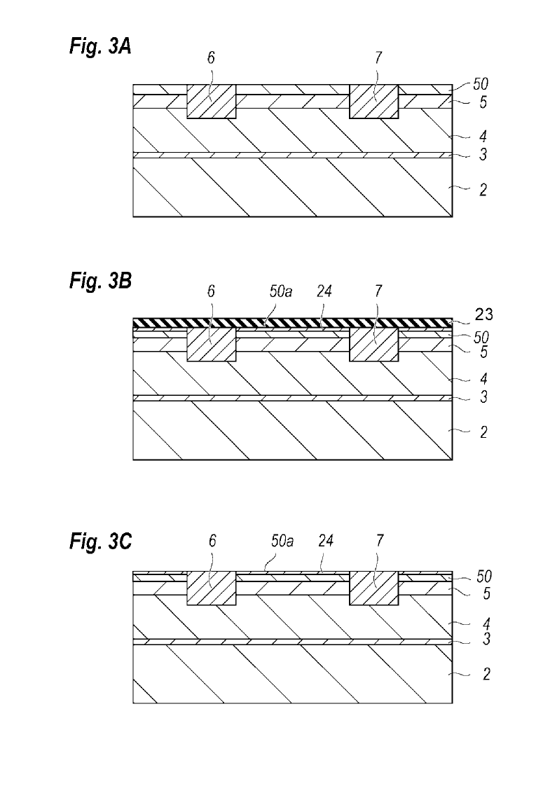

Removing the patterned photoresist 22 and the through film 21 by an organic solvent and an acid, the process exposes the surface of the cap layer 50 (FIG. 3A). Then, another insulating film 23, which may be made of silicon nitride (SiN), is deposited on the exposed surface of the cap layer 50 by the PE-CVD as an annealing film. The annealing film 23 operates as a protection film of the surface 50a of the cap layer 50 during the heat treatment of the substrate 2 and the semiconductor layers, 3 to 5 and 50, to activate the implanted impurities.

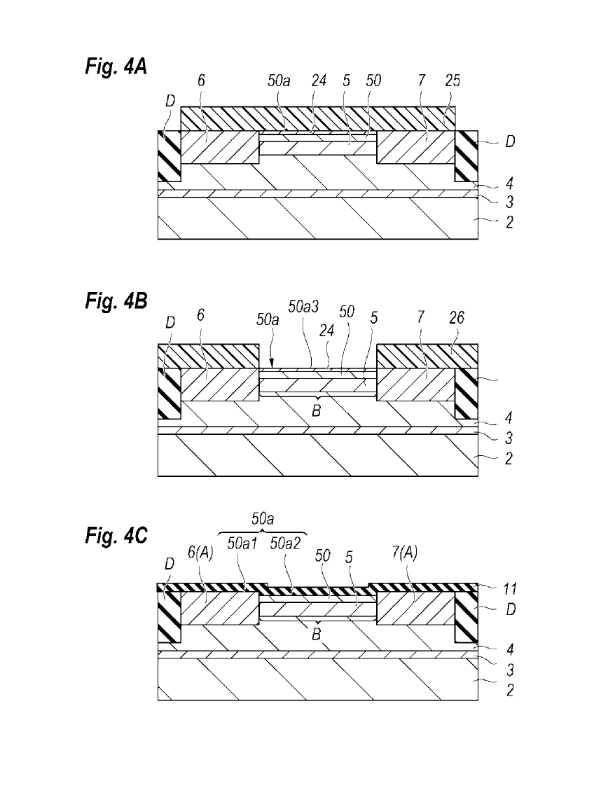

Then, the process performs the heat treatment of the substrate 2, the semiconductor layers, 3 to 5 and 50, and the annealing film 23 by, for instance, a rapid thermal annealing (RTA), or other conventional furnace anneal techniques, in an atmosphere of nitrogen (N₂) or other inert gas and a temperature not lower than 1000° C. but not exceeding 1300° C. The heat treatment thus carried out may activate the implanted impurities so as to operate as donors in the n+ regions, 6 and 7, in the cap layer 50, the barrier layer 5, and the channel layer 4. The heat treatment, or the anneal, may often induce damages on the surface 50a and a region neighbor to the surface 50a due to an interaction between elements constituting the cap layer 50, namely, gallium (Ga) and nitrogen (N), and those constituting the annealing film 23, namely, silicon (Si) and nitrogen (N). Those damages include disarrangement of the stoichiometry in the surface 50a and the region adjacent to the surface 50a primarily due to sublimation of nitrogen (N) into the annealing film 23 because of relatively higher vapor pressure thereof compared with atoms of the group III elements. The disarrangement of the stoichiometry becomes a maximum at the surface 50a. Regions denoted by a symbol 24 in FIGS. 3B to 4B, indicate those regions disarranged in the stoichiometry thereof. Although not explicitly indicated in FIG. 3B, the n+ regions, 6 and 7, also accompany with the disarranged region. The heat treatment at a temperature from 1000° C. to 1300° C. may adequately convert the implanted impurities into the donors in the n+ regions, 6 and 7, although accompanying with the disarranged region 24 in the cap layer 50. The n+ regions, 6 and 7, may have the carrier (electron) concentration of 1.0×10¹⁹ to 5.0×10²⁰ cm⁻³ which means that the sheet resistivity smaller than 200 Ω/sq. After the annealing, the process removes the annealing film 23 by an acid so as to expose the surface 50a of the cap layer 50, as shown in FIG. 3C. The disarranged region 24 after the annealing have a composition ratio of gallium (Ga) against nitrogen (N), namely Ga/N, greater than unity; that is, the disarranged region 24 has a gallium rich composition shifted from the stoichiometry composition.

Next, the process forms the isolation regions D. Specifically, the process implants carbos (C), or other atoms or ions into the cap layer 50, the barrier layer 5 and the channel layer 4 after forming another patterned photoresist 25 that covers at least a primary portion of the HEMT 1, that is, the regions A including the n+ regions, 6 and 7, and the region B between the n-type, 6 and 7, but exposes the surface 50a of the cap layer 50 in portions surrounding the primary portion as shown in FIG. 4A. Then, removing the patterned photoresist 25, the process prepares still another patterned photoresist 26 as shown in FIG. 4B, where the patterned photoresist 26 exposes the surface 50a3 of the cap layer 50 in the second region B that fully extends between the n+ regions, 6 and 7.

The process then slightly removes the surface 50a3 of the cap layer 50 thus exposed in the patterned photoresist 26. The method of the present embodiment removes the surface 50a3 in the second region B of the cap layer 50 and the disarranged region 24 slightly penetrating into the cap layer 50 by dry-etching using a reactive gas containing chloride, such as chlorine (Cl₂), boron tri-chloride (BCl₃), silicon tetrachloride (SiCl₄), or a mixture of them. Thus, the dry-etching of the disarranged region 24 leaves the un-etched surface 50a1 in the n+ regions, 6 and 7, and the depressed surface 50a2 extending fully between the n+ regions, 6 and 7, as shown in FIG. 4C. The depressed surface 50a2 has the composition ratio Ga/N smaller than that of the un-etched surface 50a1 and that of the original surface 50a3; exactly, the composition ratio Ga/N in the depressed surface 50a2 approaches the unity. Removing the patterned photoresist 26, the process forms the insulating film 11 on the cap layer 50. The surface 50a1 in the n+ regions, 6 and 7, are left un-etched, namely, the first region A, to which the source and drain electrodes, 8 and 9, are to be in contact is left un-etched. Because the dry-etching possibly induces damages on a surface to be etched, the n+ regions, 6 and 7, in the surfaces 50a1 thereof are preferably free from the dry-etching.

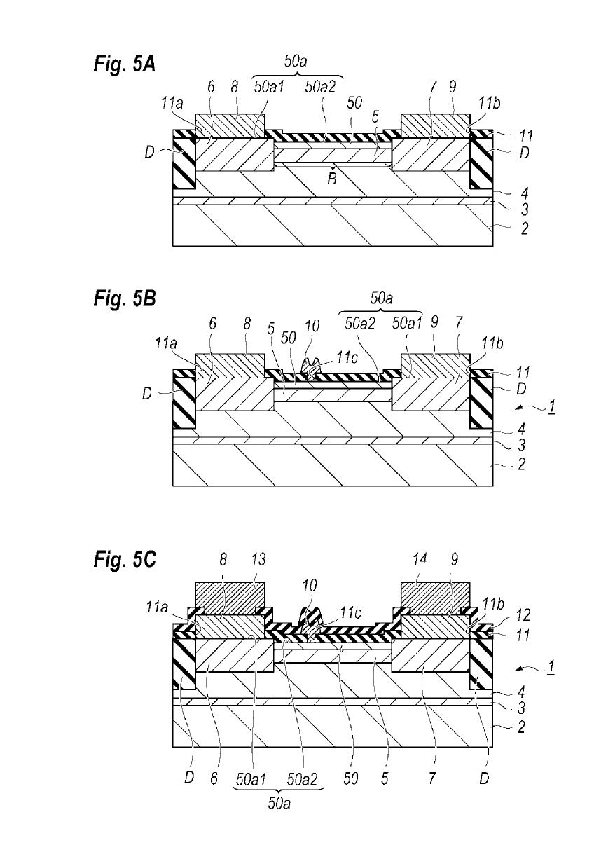

Next, forming openings, 11a and 11b, in the insulating film 11 at the n+ regions, 6 and 7; the source and drain electrodes, 8 and 9, are formed so as to be in contact to the n+ regions, 6 and 7, through the openings, 11a and 11b, by a metal evaporation and subsequent lift-off technique (FIG. 5A). The source and drain electrodes, 8 and 9, are not in contact to the cap layer 50, in particular, the cap layer 50 left between the n+ regions, 6 and 7. The edge of the source electrode 8 facing the drain electrode 9 leaves a substantial distance against the edge of the cap layer 50 facing the n+ region 6. That is, the edge of the source electrode 8 facing the drain electrode 9 retreats from the interface between the n+region 6 and the cap layer 50. Also, the edge of the drain electrode 9 facing the source electrode 8 retreats from the interface between the n+ region 7 and the cap layer 50 so as to make a distance therebetween.

Then, forming an opening 11c in the insulating film 11 left between the source and drain electrodes, 8 and 9, so as to expose the surface 50a2 of the cap layer 50, the process forms the gate electrode 10 by the metal evaporation and subsequent lift-off technique (FIG. 5B). Thus, the HEMT 1 of the present embodiment is formed. A number of HEMTs 1 are concurrently formed on the substrate 2, but the isolation region D surrounding the primary portion of the HEMT 1 may electrically isolate the HEMT 1 from other HEMTs on the substrate 2.

Finally, fully covering the respective electrodes, 8 to 10, and the insulating film 11 by the passivation film 12, and forming via holes piercing the passivation film 12 and reaching respective electrodes, 8 and 10; the process forms interconnections each electrically connected to the respective electrodes, 8 to 10, and running on the passivation film 12 (FIG. 5C). Thus, the HEMTs on the substrate 2 are electrically isolated by the isolation regions D surrounding the independent HEMT but may be electrically connected through the interconnections.

The process above described possibly induces damages in the cap layer 50 or degrades the quality, exactly, the stoichiometry of the cap layer 50 especially in the surface and the region adjacent to the surface thereof. However, the HEMT 1 according to the present invention removes the surface 50a3 and the disarranged region 24 adjacent to the surface 50a3 of the cap layer 50 so as to expose the surface 50a2 where the damages and/or the degradation of the quality is considerably reduced. Forming the gate electrode 10 on this surface 50a2, the HEMT 1 may show an extremely reduced leak current.

The process of the present invention covers the surface of the cap layer 50 by the annealing film 23 during the heat treatment at a temperature higher than 1000° C. Such a heat treatment may effectively activate the implanted impurities but inevitably cases damages on the cap layer, in particular, the sublimation of nitrogen (N) from the surface. The annealing film 23 may substantially protect the surface of the cap layer from this phenomenon but not completely prevent nitrogen (N) from sublimating from the surface and the region adjacent to the surface, which causes the increase of the leak current when the gate electrode 10 is to be formed on such a degraded surface. The HEMT 1 of the present invention forms the gate electrode 10 on the cap layer 50 on the surface 50a2 after etching the surface 50a3 and the disarranged region 24 adjacent to the surface 50a3; accordingly, the HEMT 1 may show an excellent performance in the leak current.

Also, the HEMT 1 of the present invention forms the insulating film 11 on the surface 50a2 of the cap layer 50 after removing the surface 50a3 and the disarranged region 24 adjacent to the surface 50a3. A HEMT made of nitride semiconductor materials often shows a phenomenon called as the current collapsing, where the drain current may not immediately recover the initial value after a large positive gate bias is cut. Deep traps induced in an interface between the cap layer and the insulating film and negatively charged by the current attributed to the large positive gate bias seem to be one of reasons of the current collapsing. When gallium rich surface and region are exposed to air, such surface and region easily causes a region primarily including gallium oxide (GaO) that possibly forms deep traps in the interface. The HEMT of the present invention provides the insulating film 11 formed on the surface 50a2 of the cap layer after removing the surface 50a3 and the disarranged region 24 adjacent to the surface 50a3. Accordingly, the interface between the surface 50a2 and the insulating film 11 includes deep traps originated to gallium oxide in an amount far smaller than a case where the insulating film 11 is provided on the degraded surface 50a3. Thus, the HEMT 1 of the present invention may not only reduce the leak current between the electrodes but also drastically improve the current collapsing.

The surface 50a3 and the disarranged region 24 adjacent to the surface 50a3 may be removed by etching the cap layer 50 by about 3 nm, which forms a step of about 3 nm between two surface 50a1 in the n+ regions, 6 and 7, and the second region B. Also, the source and drain electrodes, 8 and 9, preferably make gaps against the cap layer 50 in the second region B. That is, the source and drain electrodes, 8 and 9, in respective edges facing to each other, are preferably retreated from the edges of the cap layer in the second region B. Such an arrangement between the electrodes, 8 and 9, and the cap layer 50 in the second region B may reduce the leak current between the electrodes, 8 to 10.

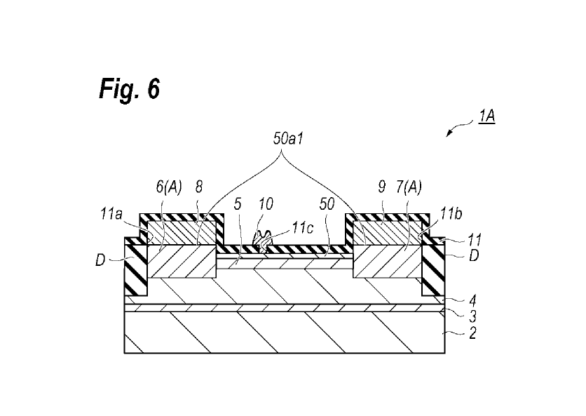

FIG. 6 shows a cross section of a HEMT 1A according to the first modification of the HEMT 1 shown in FIG. 1. The HEMT 1A provides the source electrode 8 and the drain electrode 9 fully covering the surface 50a1 of the regions A, exactly, the surfaces of the n+ regions, 6 and 7, which may lower the contact resistance of the source electrode 8 and the drain electrode 9 to the respective n+ regions, 6 and 7. Moreover, because the gate electrode 10 formed after removing the surface 50a3 and the disarranged region 24 of the cap layer 50 where the stoichiometry thereof is degraded, the leak current between the electrodes, 8 to 10, may reduce.

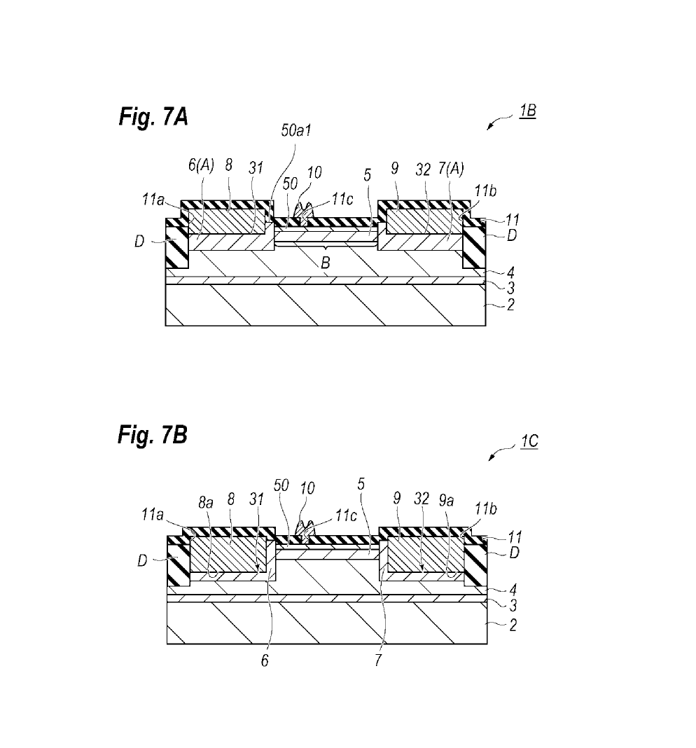

FIG. 7A shows a cross section of another HEMT 1B according to the second modification of the HEMT 1. The HEMT 1B shown in FIG. 7 has a feature distinguishable from those aforementioned in that the n+ regions, 6 and 7, provide recesses, 31 and 32, into which the source electrode 8 and the drain electrode 9 are formed. The recesses, 31 and 32, may be formed before the formation of the electrodes, 8 and 9, by selectively etching the regions A including the cap layer 50 and a portion of the barrier layer 5. That is, the recesses, 31 and 32, fully extract the cap layer 50 and reach the barrier layer 5. The recesses, 31 and 32, have bottoms deeper than the surface of the cap layer 50 in the region B. The source and drain electrodes, 8 and 9, may be formed within the recesses, 31 and 32. In an alternative, the source and drain electrodes, 8 and 9, may expand outside of the recesses, 31 and 32; that is, the source and drain electrodes, 8 and 9, may climb on the surface 50a1 of the cap layer 50 in the regions A. Because the etching for forming the recesses, 31 and 32, may fully remove the cap layer including the surface 50a1 and the disarranged region adjacent to the surface 50a1 in the regions A where the stoichiometry therein is degraded during the annealing, the electrodes, 8 and 9, may show lowered contact resistance thereto.

The implantation of the impurities through the through film 21 makes the profile of the implanted impurities closer to the surface compared with a case where the implantation is carried out for a bared surface. The removal of surface regions in the recesses, 31 and 32, makes the peak of the profile of the implanted impurities further closer to the surface, namely, the bottom of the recesses, 31 and 32. The source and gate electrodes, 8 and 9, may be formed on the surface, the bottom of the recesses, 31 and 32, having relatively greater impurity concentration after the removal of the surface 50a1 and the disarranged region adjacent to the surface 50a1, which may effectively reduce the contact resistance of the electrodes, 8 and 9, to the n+ regions, 6 and 7.

FIG. 7B shows a cross section of a HEMT 1C according to still another modification of the HEMT shown in FIG. 1. The HEMT 1C also provides the recesses, 31 and 32, but the depth thereof is far deeper than those provided in the former HEMT 1B. That is, the interfaces, 8a and 9a, of the electrodes, 8 and 9, which are equivalent to the bottoms of the recesses, 31 and 32, are deeper than the interface between the barrier layer 5 and the channel layer 4. In other words, the interfaces, 8a and 9a, of the electrodes, 8 and 9, are deeper than the 2DEG formed in the interface between the channel layer 4 and the barrier layer 5. The electrodes, 8 and 9, are buried within the n+regions, 6 and 7. In such an arrangement of the electrodes, 8 and 9, and the 2DEG in the channel layer 4, namely, the 2DEG in respective ends may become adjacent to the electrodes, 8 and 9, which considerably lowers the access resistance between the electrodes, 8 and 9, and the gate electrode 10.

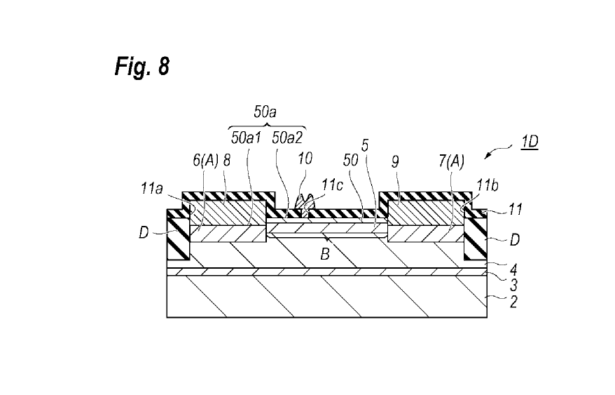

FIG. 8 shows a cross section of a HEMT 1D according to still another modification of the HEMT 1 of FIG. 1. The HEMT 1D has a feature that, comparing with the arrangement of the HEMT 1B shown in FIG. 7A, the surface 50a1 and the disarranged region adjacent to the surface 50a1 in the regions A, which are left between the electrodes, 8 and 9, and the cap layer 50, are removed. This arrangement of the electrodes, 8 and 9, and the cap layer 50 may be formed by a process by, in the process shown in FIG. 4B, removing the disarranged region 24 without preparing the patterned photoresist 26 and forming the recesses, 31 and 32, before depositing the metals for the electrodes, 8 and 9. Because the disarranged regions 24 left within the n+ regions, 6 and 7, and adjacent to the cap layer 50 are removed, the electrodes, 8 and 9, may show not only the reduced contact resistance to the n+ regions, 6 ad 7, but also the improved access resistance from the electrodes, 8 and 9, to the 2DEG in the channel. The recesses, 31 and 32, in the present modification may have depths comparable to those shown in FIG. 7B.

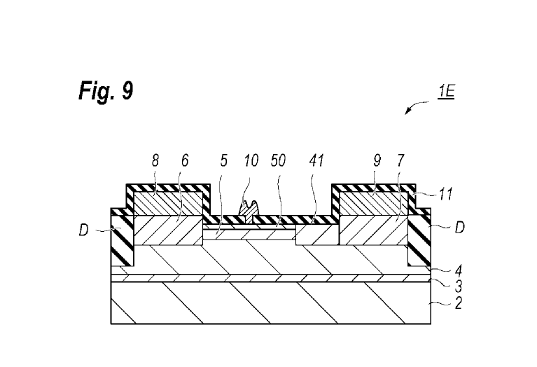

FIG. 9 shows a cross section of a HEMT 1E according to a still another modification of the HEMT 1 shown in FIG. 1. The HEMET 1F has a feature distinguishable from the HEMT 1 in that the cap layer 50, the barrier layer 5, and the channel layer 4 forms a lightly doped drain (LDD) region 41 between the gate electrode 10 and the drain electrode 9, exactly, in a side of the drain electrode 9 between the gate and drain electrodes, 10 and 9. The LDD region 41, which has doping concentration lower than the doping concentration of the n+ region 7 for the drain electrode 9, may operate as an n− region. The LDD region 41 may be formed by, after the step of the implantation of the impurities for the n+ regions, 6 and 7, shown in FIG. 2C, removing only the patterned photoresist 22 and re-preparing another patterned photoresist that provides an opening for the LDD region 41. Then, the process may implant impurities for the LDD region 41 through the through film 21 with an acceleration voltage of the implantation lower than that for the n+ regions, 6 and 7, and a dosage thereof also smaller than that for the n+ regions, 6 and 7, where the impurities for the LDD region 41 be same with those for the n+ regions, 6 and 7. Thus, the LDD region 41 may be formed by the subsequent heat treatment.

In the foregoing detailed description, the HEMTs and the process thereof according to present invention have been described with reference to specific exemplary examples. It will, however, be evident that various modifications and changes may be made thereto without departing from the broader spirit and scope of the present invention. For instance, although the specification does not explicitly describe that the surfaces of the n+ regions, 6 and 7, in the first regions A also include the surface 50a3 and the disarranged region 24 adjacent to the surface 50a3 similar to the second region B, such surface 50a3 and the disarranged region 24 cause no contribution to the increase of the leak current between the electrodes, 8 to 10. Only the disarranged region 24 left in the second region B increases the leak current. Moreover, HEMTs according to the modifications remove such disarranged region left in the n+ regions, 6 and 7, which effectively reduces the contact resistance of the source and drain electrodes, 8 and 9, to the n+regions, 6 and 7. Accordingly, the present specification and figures are accordingly to be regarded as illustrative rather than restrictive.

The present application claims the benefit of priority of Japanese Patent Application No. 2015-207341, filed on Oct. 21, 2015, which is incorporated herein by reference.

I claim:

1. A process of making a semiconductor device type of high electron-mobility transistor (HEMT) that is made of nitride semiconductor materials, comprising steps of:
growing a semiconductor stack that includes a buffer layer, a channel layer, a barrier layer, and a cap layer on a substrate;
implanting impurities into first regions of the semiconductor stack that correspond to a source region and a drain region, respectively;
forming an insulating film onto the semiconductor stack;
annealing the substrate and the semiconductor stack with the insulating film, the semiconductor stack forming a disarranged region in a surface thereof and a region adjacent to the surface;
removing the insulating film;
removing at least a portion of the disarranged region extending fully between the first regions so as to form a second region between the first regions; and
forming a gate electrode onto the semiconductor stack in the second region.

2. The process of claim 1,
wherein the step of annealing is carried out at a temperature not lower than 1000° C. but not higher than 1300° C.

3. The process of claim 1,
wherein the step of annealing forms the disarranged region has a composition ratio of group III elements against nitrogen (N) greater than unity

4. The process of claim 1,
further including a step of forming another insulating film on the semiconductor stack at least in the second region after the step of removing the portion of the disarranged region in the second region,
wherein the step of forming the gate electrode includes steps of forming an opening in the another insulating film so as to expose the surface of the semiconductor stack where the disarranged region is removed, and depositing metals onto the exposed surface of the semiconductor stack within the opening in the another insulating film.

5. The process of claim 1,
further including a step of forming a through film before the step of implanting impurities,
wherein the step of implanting includes steps of implanting the impurities through the through film, and removing the through film after the step of implanting the impurities.

6. The process of claim 5, further including steps of:
forming recesses in the first regions implanted with the impurities after the step of removing the insulating film; and
forming a source electrode and a drain electrode within the respective recesses.

7. The process of claim 6,
wherein the step of forming the recesses includes a step of fully removing the cap layer in the first regions so as to expose the barrier layer but leaving at least a portion of the barrier layer.

8. The process of claim 6,
wherein the step of forming the recesses includes a step of fully removing the cap layer and the barrier layer but leaving at least a portion of the channel layer in the first regions.

9. A semiconductor device type of high electron-mobility transistor (HEMT) made of nitride semiconductor materials, comprising:
a semiconductor stack provided on a substrate, the semiconductor stack including, from a side of the substrate, a buffer layer, a channel layer, a barrier layer, and a cap layer;
n+ regions providing in the semiconductor stack, the n+ regions being laterally apart from each other with a space therebetween and including implanted impurities;
an insulating film that covers a surface of the semiconductor stack in the space, the insulating film having an opening;
a gate electrode directly in contact to the surface of the semiconductor stack through the opening; and
a source electrode and a drain electrode provided on the surfaces of the n+ regions, respectively,
wherein the surface of the semiconductor stack in the space in a horizontal level thereof is lower than the surfaces of the n+ regions.

10. The semiconductor device of claim 9,
wherein the surface of the semiconductor stack in the space is at least 3 nm lower than the surfaces of the n+ regions.

11. The semiconductor device of claim 9,
wherein the n+ regions have recesses into which the source electrode and the drain electrode are formed, the recesses reaching the barrier layer in the n+ regions.

12. The semiconductor device of claim 9,
wherein the n+ regions have recesses into which the source electrode and the drain electrode are formed, the recesses reaching the channel layer in the n+regions.

13. The semiconductor device of claim 9,
wherein the channel layer, the barrier layer, and the cap layer are made of gallium nitride (GaN) with a thickness not thinner than 4 nm but not thicker than 50 nm, aluminum gallium nitride (AlGaN) with a thickness not thinner than 1 nm but not thicker than 30 nm, and GaN with a thickness of not thinner than 0.5 nm but not thicker than 10 nm, respectively.
